(19) United States
(12) Patent Application Publication
(10) Pub. No.: US 2016/0338230 A1
(43) Pub. Date: Nov. 17, 2016

(54) CONTROL OF THERMAL ENERGY TRANSFER FOR PHASE CHANGE MATERIAL IN DATA CENTER

(71) Applicant: Advanced Micro Devices, Inc., Sunnyvale, CA (US)

(72) Inventors: Fulya Kaplan, Boston, MA (US); Manish Arora, Dublin, CA (US); Wayne P. Burleson, Shutesbury, MA (US); Indrani Paul, Round Rock, TX (US); Yasuko Eckert, Bellevue, WA (US)

(21) Appl. No.: 14/709,655

(22) Filed: May 12, 2015

(51) Int. Cl. H05K 7/20

(52) U.S. Cl. CPC H05K 7/20836; H05K 7/205

(57) ABSTRACT

A cooling system controller for a set of computing resources of a data center includes a first interface to couple to a first flow controller that controls a rate of thermal energy transfer to a PCM store from the set of computing resources, a second interface to couple to a second flow controller that controls a rate of thermal energy transfer from the PCM store to a cooling system, and a controller to determine a current set of operational parameters for the data center and to manipulate the first and second flow controllers and via the first and second interfaces to control a net thermal energy transfer to and from the PCM store based on the current set of parameters.

### BACKGROUND

1. Field of the Disclosure

The present disclosure relates generally to data center cooling systems and, more particularly, to use of phase change materials in data center cooling systems.

2. Description of the Related Art

Energy costs for providing sufficient cooling of computing resources typically constitute a large percentage of the total energy costs for operating a data center. Conventionally, the thermal energy generated by computing resources is evacuated as heated air, which is subsequently cooled by one or more computer room air conditioner (CRAC) units. The cooled air is then circulated back to the computing resources. Phase change materials (PCMs) increasingly have been considered for use in absorbing thermal energy expended by computing resources due to their latent heat properties. However, conventional approaches to implementing PCMs provide a sub-optimal balance between energy costs for cooling and other objectives, such as cooling performance.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of a data center having a cooling system utilizing a PCM store in accordance with some embodiments.

FIG. 2 is a diagram illustrating a multiple-rack implementation of the PCM store of FIG. 1 in accordance with some embodiments.

FIG. 3 is a diagram illustrating a rack-based implementation of the PCM store of FIG. 1 in accordance with some embodiments.

FIG. 4 is a diagram illustrating a circuit board-based implementation of the PCM store of FIG. 1 in accordance with some embodiments.

FIG. 5 is a diagram illustrating an example implementation of a cooling system controller of the cooling system of FIG. 1 in accordance with some embodiments.

FIG. 6 is a flow diagram illustrating an example method of multivariate cooling control using a PCM store in accordance with some embodiments.

### DETAILED DESCRIPTION

The latent heat properties of phase change materials (PCMs) allows thermal energy generated by a computing resource to be transferred from the computing resource to a store of PCM without raising the temperature of the PCM while it is in its state-transition phase. At a subsequent time when the electricity prices are lower (as often is the case at night), the PCM store can be cooled to return it to its original state. Thus, the energy expended in cooling the data center may be somewhat time shifted to a point where the costs of the energy expended for cooling are lower, which in turn lowers the overall cost of running the data center. However, time-shifting the cooling of the PCM store is only a partial solution. The thermal energy absorption capacity of the PCM store is limited; once the all of the PCM has changed state (e.g., from solid to liquid, or from liquid to gas), any additional heat input results in a rise in the temperature of the PCM store. Thus, once the constant-temperature heat absorption capacity of the PCM store has been reached, the PCM store ceases to operate as a cooling mechanism. This situation eliminates the ability for the PCM store to act as a cooling “backup” in the event that the thermal output of the computing resources increases (i.e., the workload of the computing resources increases), which results in the computer room air conditioner (CRAC) unit having to expend additional energy at a time when electricity costs are likely higher to compensate for the increased thermal output. Moreover, the CRAC unit may have been designed on the assumption that the PCM store would be available to absorb some of the thermal energy at all times, and thus the additional cooling performance needed from the CRAC unit once the PCM store reaches its latent heat absorption capacity may overwhelm the CRAC unit, leading to shut down or overheating of the computing resources.

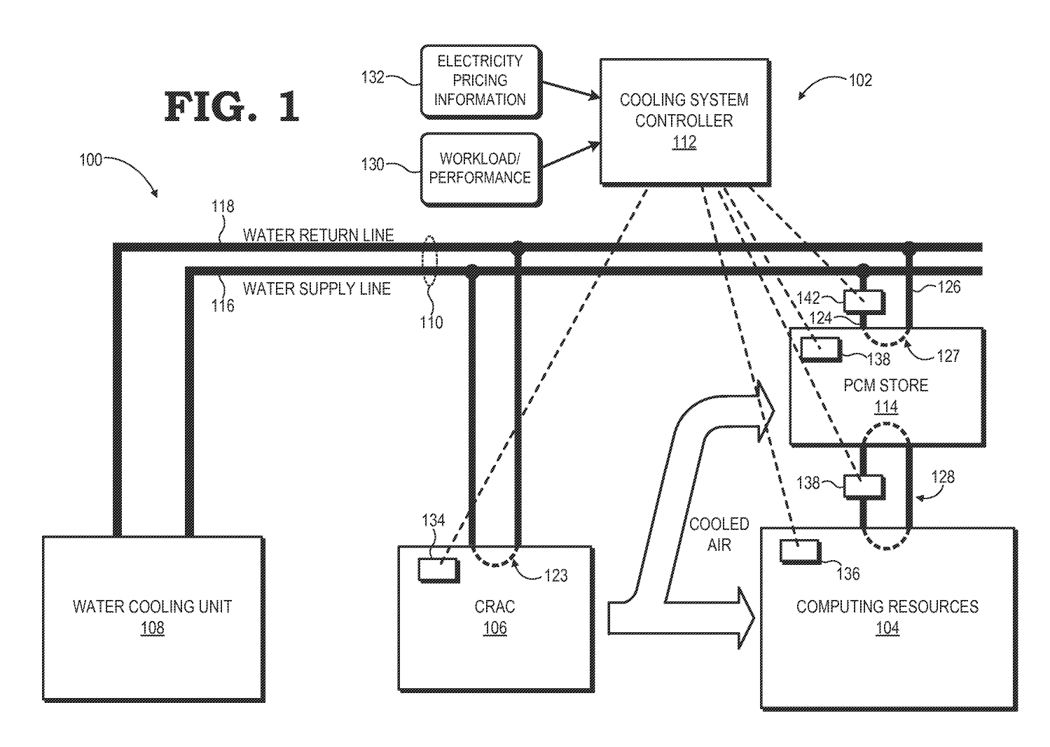

FIGS. 1-6 illustrate example systems and techniques to provide a more optimal usage of a PCM store in a data center cooling system. In at least one embodiment, in addition to controlling the cooling of a PCM store, a cooling system also controls the transfer of thermal energy from computing resources to the PCM store. That is, the cooling system controls both the thermal energy input rate as well as the thermal energy output rate of the PCM store. To this end, the cooling system monitors various operational parameters of the data center, and makes decisions on thermal energy input and output rates for the PCM store based on multiple objectives. For example, the cooling system may monitor current and future electricity prices, current and future workloads, and current remaining PCM latent heat absorption capacity (hereinafter, “latent heat capacity”), and select a rate of thermal transfer into the PCM store that achieves a suitable balance between the cost savings of time-shifting PCM cooling with the advantages of maintaining some latent heat capacity of the PCM store in view of upcoming workloads predicted to be performed by the computing resources.

The PCM store may be implemented on a multiple-rack basis, whereby a relatively large amount of PCM is utilized to absorb the thermal energy from multiple server racks of a data center, such as from one or more rows of racks, one or more rooms of racks, or the entire data center. Alternatively, the PCM store may be implemented on an individual rack basis, whereby a moderate amount of PCM is stored at a server rack and used to absorb the thermal energy from one or more server units of the server rack transported to the PCM via a heat pipe system comprising one or more heat pipes or other heat transfer mechanisms. In such instances, the PCM may be integrated into the rack structure itself, such as within the walls or roof of the rack, or in a modular structure that is shaped like a server unit so that it may be inserted and mounted into a server rack in a manner similar to a typical server unit. In yet other embodiments, the PCM store may be implemented on an individual server unit basis, whereby a relatively small amount of PCM is stored within the server unit, and is used to absorb the thermal energy from one or more components on the circuit board of the server unit via heat pipes or other heat transfer mechanisms. Further, in some embodiments, the cooling system may implement a combination of the multiple-rack, individual-rack, and individual-server-unit approaches.

FIG. 1 illustrates a data center 100 using a PCM store for thermal energy storage in accordance with at least one embodiment of the present disclosure. The data center 100 implements a cooling system 102 to cool one or more computing resources 104. Depending on the scope of implementation, the computing resources 104 may include individual components of a server unit, such as the components of a motherboard or other circuit board, multiple server units within a server rack, or multiple server racks, such as one or more rows of server racks or all of the server racks of the data center 100.

In the depicted embodiment, the cooling system 102 includes one or more CRAC units 106, a water cooling unit 108, a set 110 of water lines, a cooling system controller 112, and one or more PCM stores 114. For ease of illustration, the set 110 of water lines is illustrated as a single water supply line 116 and a single water return line 118. However, in many instances the set of water lines may comprise multiple water supply lines and multiple water return lines. Moreover, there may be different classes of water lines, such as hot water lines, warm water lines, and cool water lines. Further, although water-based implementations are described herein, the techniques described herein can utilize any of a variety of fluids frequently used for cooling, and thus reference to “water” also is a reference to other cooling fluids unless otherwise noted. The water cooling unit 108 includes an inlet coupled to the water return line 118 and an outlet coupled to the water supply line 116. The CRAC unit 106 is connected to the water supply line 116 and water return line 118 via lines 120 and 122, respectively. These lines 120 and 122 in turn are coupled to internal piping in the CRAC UNIT 106, thereby forming a cooling loop 123 in the CRAC UNIT 106. The PCM store 114 is connected to the water supply line 116 and water return line 118 via lines 124 and 126, respectively. The lines 124 and 126 are coupled to the inlet and outlet, respectively, of an internal circulation system in the PCM store 114, thereby forming a cooling loop 127 in the PCM store 114.

The PCM store 114 contains a store of one or more PCMs. Examples of such PCMs can include, for example, organic paraffins, metal eutectics, salt hydrates, or combinations thereof. The particular PCM or combination of PCMs may be selected based on a match between the desired operational temperature of the computing resources 104 and the melting point of the PCM or blend of PCMs. Moreover, the amount of PCM implemented in the PCM store 114 may be determined based on desired thermal energy absorption capacity, cost limitations, space limitations, environmental factors, and the like. To facilitate thermal energy transfer into the PCM of the PCM store 114, the cooling system 102 further includes a heat transfer system 128 that thermally couples the computing resources 104 to the PCM store 114. The heat transfer system 128 can comprise, for example, one or more heat pipes, one or more water circulation loops, or a combination thereof. For ease of illustration, an example implementation of the heat transfer system 128 as a water circulation loop is used in the following description.

In operation, the computing resources 104 are assigned workloads by a job dispatch system (not shown) of the data center 100. In the course of processing these workloads, the computing resources generate considerable heat, with the amount of heat generated relatively proportional to the workload of the computing resource 104. To evacuate the thermal energy generated by the computing resources 104, the CRAC unit 106 utilizes the cold water supplied through the cooling loop 123 to cool a flow of air, which in turn is circulated though the computing resources 104. Moreover, the heat transfer system 128 can be used to bolster the cooling process by transferring thermal energy generated by the computing resources 104 to the PCM of the PCM store 114. This thermal energy is absorbed by the PCM as latent heat (that is, through the change of state from solid to liquid or from liquid to gas without an increase in temperature of the PCM) until the latent heat capacity of the PCM has been exhausted, at which point the temperature of the PCM increases in the event that additional thermal energy is transferred. Thus, to maintain latent heat capacity of the PCM, cooling water may be circulated through the PCM store 114 via the cooling loop 127, thereby transferring thermal energy from the PCM into the water of the water return line 118. The water cooling unit 108 in turn operates to cool the water received via the water return line 118, which then may be recirculated through the cooling system 102 as water in the water supply line 116. Moreover, the PCM store 114 may be cooled by the cooled air from the CRAC unit 106, and thus the PCM store 114 may incorporate fans to draw the cooled air over the PCM or heat sinks to facilitate convection of thermal energy from the PCM into the cooled air.

The process of cooling the water in circulated in the set 110 of water lines consumes considerable power, typically in the form of electricity. As the cost of electricity often fluctuates, typically on an intra-daily basis, the PCM store 114 ideally would be sized so as to permit the PCM store 114 to continually absorb thermal energy from the computing resources 104 without consuming all latent heat capacity of the PCM until the cost of electricity has reached its lowest point of the day, at which point the cooling loop 127 could be activated so as to allow the PCM store 114 to be cooled down at the lowest cost. For example, assuming electricity is cheapest at night, the PCM store 114 would be sized to allow the PCM store 114 to continuously absorb all thermal energy not readily evacuated by the CRAC UNIT 106 during the day while retaining some thermal heat capacity at the end of the day, at which point the water cooling unit 108 can cool the PCM store 114 at the lowest electricity prices of the day. However, a PCM store 114 of this size often is not practicable for size, cost, or environmental reasons. As such, in a conventional system, a PCM store may have its latent heat capacity exhausted long before the optimal time to commence cooling of the PCM store, which in turn requires either cooling the PCM store at a sub-optimal time with respect to the cost of power, or permitting the operating temperature of the computing resources 104 to rise due to the inability of the PCM store to absorb any more thermal energy without also experiencing an increase in temperature.

Accordingly, in at least one embodiment, the cooling system controller 112 operates to control both the rate of thermal energy transfer to the PCM store 114 (that is, the “thermal input rate” to the PCM store 114) and the rate of thermal energy from the PCM store 114 (that is, the “thermal output rate” from the PCM store 114) so as to achieve a suitable balance between the cost of power used to cool the PCM store 114 and the maintenance of reserve latent heat capacity in view of predicted future workloads of the computing resources. As such, the cooling system controller 112 monitors various operational parameters of the cooling system 102 and the data center 100 as a whole, and based on these operational parameters the cooling system controller 112 determines a suitable setting for both the thermal input rate and thermal output rate for the PCM store 114.

To this end, the cooling system controller 112 has interfaces coupled to various components of the data center 100 via wired or wireless connections. To illustrate, the cooling system controller 112 may include an interface to a job dispatch system (not shown) of the data center 100 to obtain workload/performance information 130 regarding the current workload or performance state of the computing resources 104 as well as future workloads/performance states of the computing resources 104 based on workloads dispatched to the computing resources. As another example, the cooling system controller 112 may include an interface to a remote network or a database (not shown) that provides electricity pricing information 132 for current and future energy prices. For example, the electric utility providing electricity to the data center may publish or otherwise make available its current and predicted future electricity prices, and the cooling system controller 112 may have an interface to this information source. As another example, the cooling system controller 112 or a third-party may maintain a database of historical energy prices, and from this information the cooling system controller 112 can predict the current and future energy prices from the historical energy price information. Thus, reference to current and future energy prices can comprise actual energy prices or predicted energy prices.

The cooling system controller 112 further may include interfaces to monitor the current operational status of the CRAC UNIT 106, the computing resources 104, and the PCM store 114. To illustrate, the cooling system controller 112 may interface with a controller 134 of the CRAC UNIT 106 to determine the current operational state of the CRAC unit 106, and from this the cooling system controller 112 may determine the remaining additional capacity the CRAC UNIT 106 may have available to provide additional cooling if needed. Further, in some embodiments the cooling system controller 112 may control the cooling performance of the CRAC unit 106 via the controller 134. Additionally, the cooling system controller 112 may interface with a monitoring unit 136 co-located with the computing resources 104 and which monitors the temperature of the computing resources 104. Likewise, a monitoring unit 138 located at the PCM store 114 monitors and reports the temperature of the PCM to the cooling system controller 112.

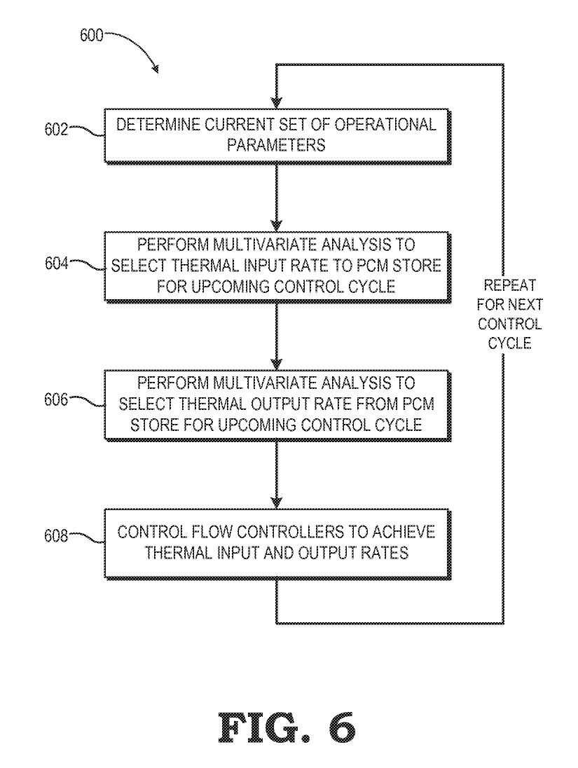

The heat transfer system 128 between the computing resources 104 and the PCM store 114 includes a flow controller 140 that controls the rate of thermal energy transfer from the computing resources 104 to the PCM store 114. Similarly, the cooling loop 127 between the PCM store 114 and the set 110 of water lines includes a flow controller 142 that controls the rate of thermal energy transfer from the PCM store 114 to the circulating water. The flow controllers 140, 142 may control this rate by controlling the rate of fluid circulation in their respective circulation loops and thus can include, for example, electronically actuated valves that can serve to restrict flow, variable-speed pumps or circulators that can serve to propel the fluid circulation at a variety of speeds, or a combination thereof. Thus, to control the input thermal rate—that is, the transfer of thermal energy from the computing resources 104 to the PCM store 114—the cooling system controller 112 controls the flow controller 140 of the heat transfer system 128 via wired or wireless signaling to implement a particular fluid circulation rate in the heat transfer system 128 that correlates to the selected input thermal rate. Likewise, to control the output thermal rate—that is, the transfer of thermal energy from the PCM store 114 into the water circulated through the water cooling unit 108—the cooling system controller 112 controls the flow controller 142 of the cooling loop 127 via wired or wireless signaling to implement a particular fluid circulation rate in the cooling loop 127 that correlates to the selected output thermal rate. Example processes for selecting a particular input thermal rate or a particular output thermal rate are described below with reference to FIGS. 5 and 6.

As described in greater detail below, the cooling system controller 112 controls the net thermal transfer rate to and from the PCM store 114 based on multiple objectives. That is the net thermal transfer rate (which may be a positive or negative value) into the PCM store 114 is controlled by cooling system controller 112. A primary objective in this regard is the reduction of the costs of cooling by timing the usage of electricity for cooling operations to align with time periods when electricity costs are lower. Thus, all else being equal, the cooling system controller 112 controls the cooling loop 127 so that the rate of thermal energy transfer from the PCM store 114 to the circulated cooled water is increased when current electricity prices are determined to be lower than the electricity prices in the near future and the rate of thermal energy transfer from the PCM store 114 is decreased when the current electricity prices are determined to be higher than the electricity prices in the near future. Conversely, the cooling system controller 112 controls the heat transfer system 128 to decrease the rate of thermal energy transfer from the computing resources 104 to the PCM store 114 when the current electricity prices are determined to be lower than the electricity prices in the near future and the rate of thermal energy transfer to the PCM store 114 is increased when the current electricity prices are determined to be higher than the electricity prices in the near future. Moreover, other considerations, such as upcoming workloads or performance states of the computing resources 104 (which in turn represent the amount of thermal energy needing to be evacuated), the remaining latent heat capacity of the PCM store 114, and remaining cooling performance of the CRAC unit 106, may be considered for selection of one or both of the thermal input rate and thermal output rate for an upcoming control cycle.

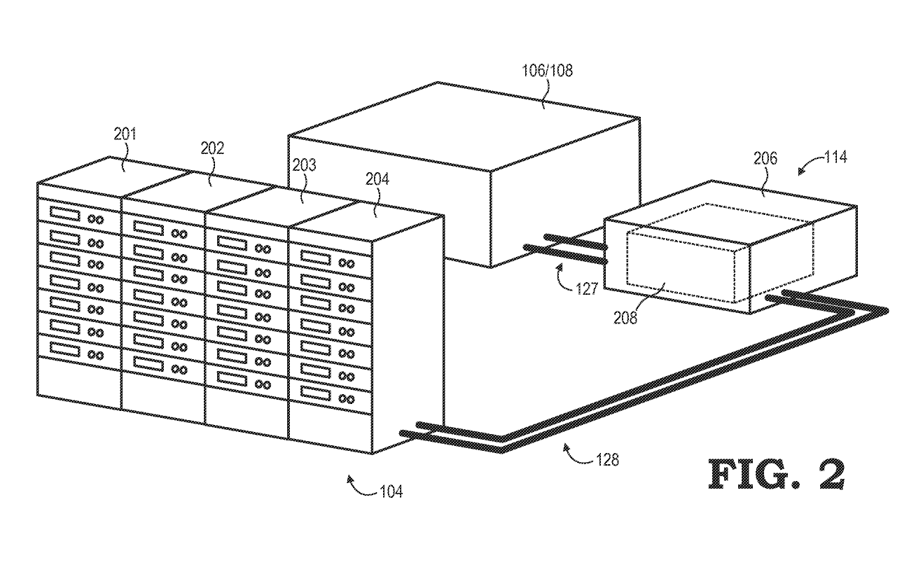

FIGS. 2-4 illustrate various example implementations of the computing resources 104 and the PCM store 114 in accordance with some embodiments. FIG. 2 depicts a multiple-rack implementation whereby the computing resources 104 are implemented as a set of server racks, such as server racks 201, 202, 203, and 204, and the PCM store 114 is implemented as a large external PCM storage unit 206 that stores a quantity of PCM 208 sufficient for providing supplemental thermal energy absorption capacity for the multiple server racks. In this implementation, the heat transfer system 128 may comprise heat piping or cooling circulation piping that runs through the server racks and serves to transfer the thermal energy output by the server racks to the PCM 208.

The efficiency of a heat exchange system, such as that implemented in the CRAC unit 106 to cool the circulated air or that implemented in the water cooling unit 108 to cool the circulated water, is based on the difference between the hot and cold temperatures of the heat exchange system. Accordingly, in some embodiments, the efficiency of the heat exchange system of the CRAC unit 106 or the water cooling unit 108 can be improved by positioning the PCM storage unit 206 in proximity to the heat exchange system. In this approach, while the PCM 208 retains latent heat capacity, the PCM storage unit 206 can absorb thermal energy from the set of server racks without increasing in temperature, thereby maintaining a lower differential between the hot and cold temperatures of the heat exchange system, and thus improving its efficiency. Thus, in one embodiment, the PCM storage unit 206 may be integrated with the water cooling unit 108 such that the PCM 208 is cooled by water circulated from the water cooling unit 108 via the cooling loop 127. Alternatively, the PCM storage unit 206 may be integrated with the CRAC unit 106, which operates to cool the PCM 208 via cooled water generated by the CRAC unit 106 through the cooling loop 127 or via cooled air circulated by the CRAC unit 106 over the PCM 208.

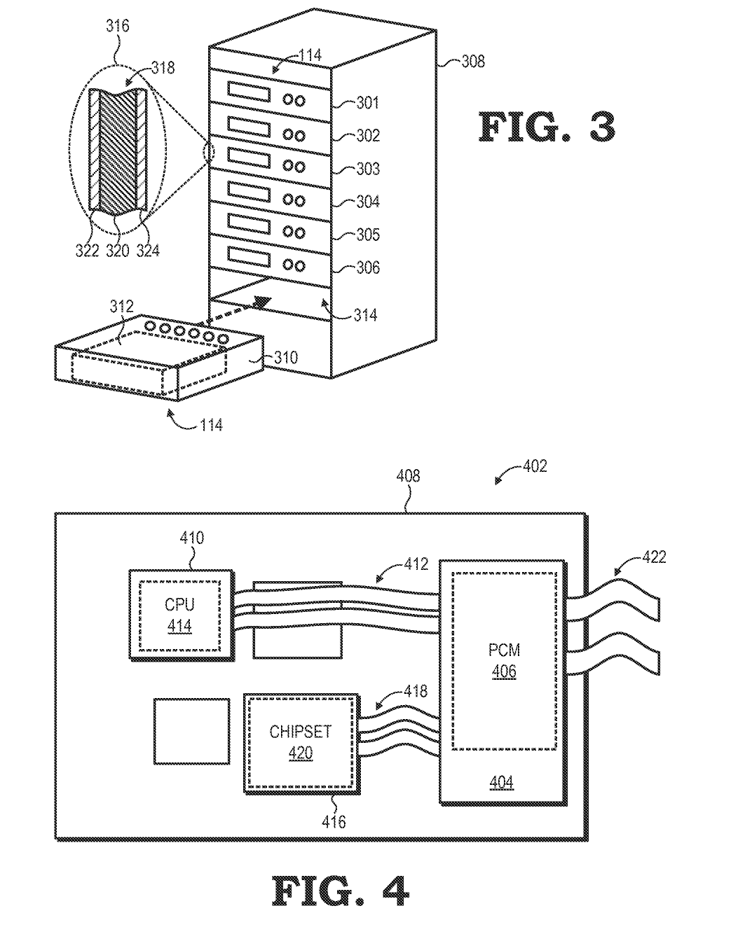

FIG. 3 depicts a single-rack implementation whereby the computing resources 104 are implemented as a set of server units, such as server units 301, 302, 303, 304, 305, and 306 of a server rack 308, and the PCM store 114 is integrated within the server rack 308 to provide supplemental thermal energy absorption capacity for the multiple server units of the server rack 308. In this implementation, the PCM store 114 may be implemented as a modular PCM storage unit 310 that contains PCM 312 and which has a server unit form factor that permits it to be inserted into a rack space 314 of the server rack 308 in a manner similar to the insertion of the server units 301-306 into the server rack 308. In this manner, the modular PCM storage unit 310 may receive supply voltages using the same voltage supply mechanisms as the server units 301-306, and can utilize the network interface provided by the backplane of the server rack 308 to provide the network connectivity with the cooling system controller 112, which also may be implemented within the server rack 308. Moreover, in some embodiments, the server rack 308 may implement multiple modular PCM storage units 310. To illustrate, a 4U rack space 314 may be used to incorporate four modular PCM storage units 310 having a 1U rack unit form factor.

Moreover, the structure of the server rack 308 itself may be implemented as the PCM store 114. For example, as illustrated by the cross-section view of detail window 316, one or more of sides of a casing 318 of the server rack 308 may be formed as a hollow-wall structure so as to allow the placement of PCM 320 and associated circulation piping (not shown) between casing walls 322 and 324. Heat piping or fluid circulation piping then may be connected between the server units 301-306 (as computing resources 104) and a set of circulation piping running through the PCM 320 within the casing 318 so as to permit transfer of thermal energy generated by the server units 301-306 into the PCM 320. Likewise, thermal energy may be transferred from the PCM 320 into the circulated cooled water via a separate set of circulation piping running through the PCM 320 or via cooled air circulated through and around the casing 318 of the server rack 308.

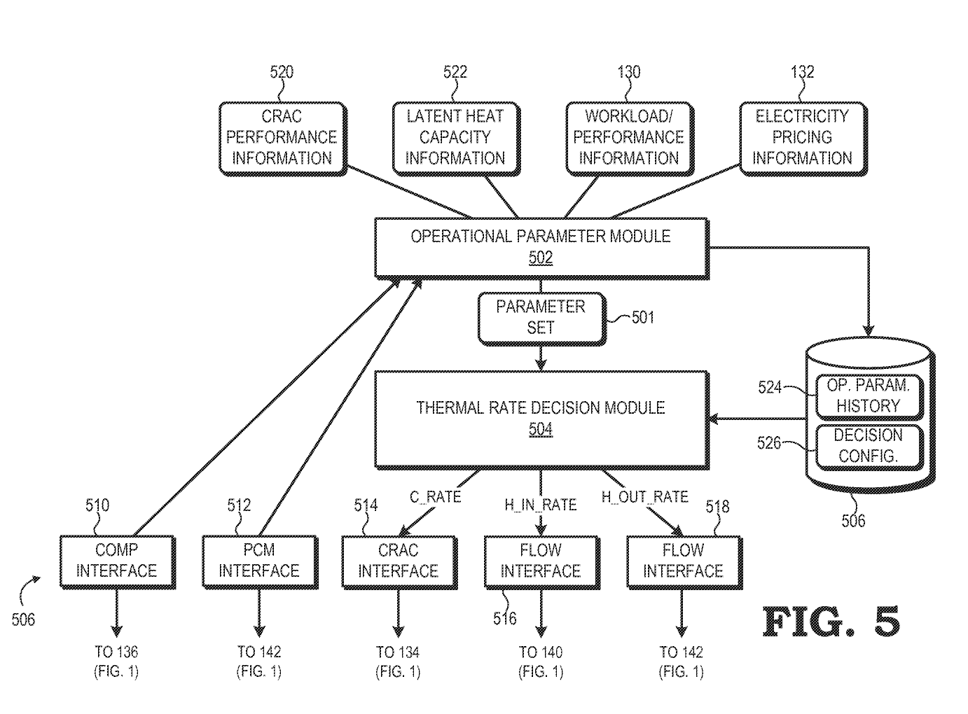

FIG. 4 depicts an example single server unit implementation whereby the computing resources 104 comprise the computing resources of a single server unit 402 and the PCM store 114 is implemented as a PCM storage unit 404 containing PCM 406 and which is integrated with the server unit 402. In this implementation, cold plates and heat piping are used to transfer thermal energy from one or more computing resources on a circuit board 408 to the PCM storage unit 404, which may be mounted on the circuit board 408 or disposed elsewhere within the server unit 402 (e.g., at the top surface or bottom surface of the server unit 402). For example, a cold plate 410 and heat piping 412 may be used to transfer thermal energy generated by a central processing unit (CPU) 414 of the circuit board 408 to the PCM storage unit 404, and a cold plate 416 and heat piping 418 can be used to transfer thermal energy from a chipset 420 to the PCM storage unit 404. Thermal energy is transferred from the PCM storage unit 404 via piping 422. In one embodiment, multiple server units within a rack each may implement a separate PCM storage unit 404, and the piping 422 from each PCM storage unit 404 may be aggregated into a single inlet line and a single outlet line, which are routed to either the CRAC unit 106 or the water cooling unit 108.

FIG. 5 illustrates an example implementation of the cooling system controller 112 of the cooling system 102 of FIG. 1 in accordance with at least one embodiment. In the depicted embodiment, the cooling system controller 112 comprises an operational parameter module, a thermal rate decision module 504, and a set 505 of interfaces to components of the data center 100, including: a computing resource interface 510 connected to the monitoring unit 136 (FIG. 1) of the computing resources 104, a PCM interface 512 connected to the monitoring unit 138 (FIG. 1) of the PCM store 114, a CRAC interface 514 connected to the controller 134 (FIG. 1) of the CRAC unit 106, a flow interface 516 connected to the flow controller 140 (FIG. 1) of the heat transfer system 128 and a flow interface 518 connected to the flow controller 142 (FIG. 1) of the cooling loop 127 (FIG. 1). The cooling system controller 112 further can include or have access to one or more data stores 506, which may be implemented as part of the cooling system controller 112 or locally accessible to the cooling system controller 112, or which may be remotely accessible from a server via a network.

The operational parameter module 502 and the thermal rate decision module 504 each may be implemented entirely in hard-coded logic (that is, hardware), as a combination of software stored in a non-transitory computer readable storage medium and one or more processors to access and execute the software, or as combination of hard-coded logic and software-executed functionality. Such processors can include a central processing unit (CPU), a graphics processing unit (GPU), a microcontroller, a digital signal processor, a field programmable gate array, programmable logic device, state machine, logic circuitry, analog circuitry, digital circuitry, or any device that manipulates signals (analog and/or digital) based on operational instructions that are stored in one or more non-transitory computer readable storage media. The non-transitory computer readable storage media storing such software can include, for example, a hard disk drive or other disk drive, read-only memory, random access memory, volatile memory, non-volatile memory, static memory, dynamic memory, flash memory, cache memory, and/or any device that stores digital information. Note that when the processing module implements one or more of its functions via a state machine, analog circuitry, digital circuitry, and/or logic circuitry, the memory storing the corresponding operational instructions may be embedded within, or external to, the circuitry comprising the state machine, analog circuitry, digital circuitry, and/or logic circuitry.

The operational parameter module 502 operates to determine a set 501 of various operational parameters of the data center 100 that pertain to the thermal input/output rate decision process. Such operational parameters can include current and future electricity prices (or predictions thereof) from the aforementioned electricity pricing information 132 and current and future workload estimates or predictions from the workload/performance information 130. The operational parameter module 502 further can utilize the CRAC interface 514 to obtain CRAC performance information 520, and from this determine one or more operational parameters pertaining to the CRAC unit 106, such as the current CRAC cooling performance or an unused cooling capacity remaining at the CRAC unit 106.

Moreover, the operational parameter module 502 can use the PCM interface 512 to determine various operational properties from latent heat capacity information 522 obtained for the PCM store 114, such as whether the latent heat capacity of the PCM store 114 has been entirely consumed or the amount of latent heat capacity currently remaining at the PCM store 114. To illustrate, as a PCM maintains a constant temperature while changing states, the monitoring unit 136 of the PCM store 114 can utilize a thermal sensor to determine the current temperature of the PCM, and from this temperature determine whether any latent heat capacity remains in the PCM store 114. That is, if the temperature of the PCM is at or below the melting point (or boiling point for a liquid-gas type of PCM), then the operational parameter module 502 can assume that there is some latent heat capacity remaining for the PCM. However, if the temperature of the PCM is measurably above the melting point, then the operational parameter module 502 can assume that all of the PCM has changed state and thus no unused latent heat capacity remains. As another example, the monitoring unit 136 may utilize an ultrasound sensor, volumetric change sensor, or other mechanism for determining a proportion of melted PCM to solid PCM (or a proportion of vaporized PCM to liquid PCM), and from this estimate a current remaining latent heat capacity of the PCM store 114.

In at least one embodiment, as each set of operational parameters is determined for a current time point, representations of some or all of the operational parameters also are stored in a operational parameter history database 524, thereby compiling a history of the operational parameters, which may be used by the operational parameter module 502 to estimate or predict certain operational parameters. As one example, the operational parameter module 502 may maintain a history of electricity prices, and from this history determine a relationship between electricity price and time of day or day of week, and from this predict electricity prices going forward. As another example, the operational parameter history database 524 may contain operational parameters reflecting the workload status of the computing resources 104 and remaining latent heat capacities for corresponding points in time, and from this the operational parameter module 502 may determine a relationship between workload level of the computing resources 104 and corresponding consumption of latent heat capacity of the PCM store 114 for a given thermal input rate, and thus the operational parameter module 502 may predict the rate of consumption of latent heat capacity by the computing resources 104 at a given workload level and for a given thermal input rate.

The thermal rate decision module 504 utilizes sets of operational parameters provided by the operational parameter module 502 to select a thermal input rate (denoted “H_IN_RATE” in FIG. 5) and a thermal output rate (denoted “H_OUT_RATE” in FIG. 5) for the PCM store 114 for the next control cycle and configure the flow controllers 140 and 142 (FIG. 1) via the flow interfaces 516 and 518, respectively, so as to implement the selected thermal input and output rates. In at least one embodiment, the thermal rate decision module 504 selects the thermal input and output rates based on application of a multivariate analysis that seeks to balance multiple objectives. To illustrate, in a conventional approach, the thermal energy would be continuously transferred without any rate control to the PCM store 114 until its latent heat ability is saturated and at some later point the PCM would be cooled when electricity prices are lower. However, in the meantime any additional thermal energy transferred from the computing resources 104 would simply raise the temperature of the PCM in the PCM store 114. As such, a workload spike in the computing resources 104 while the PCM store 114 has reached its latent heat capacity could overtax the CRAC unit 106 as it deals with both cooling the computing resources 104 during the workload spike and cooling the PCM store 114 as well. In contrast, the thermal rate decision module 504 may, for example, detect from the workload/performance information 130 that a workload spike for the computing resources 104 is upcoming, and thus elect to reduce the thermal input rate, or periodically suspend all thermal energy transfer, until that point so that there is latent heat capacity remaining in the PCM store 114 for the workload spike. This would allow the PCM store 114 to absorb the additional thermal energy from the workload spike without requiring additional cooling performance from the CRAC unit 106, and thus overtaxing of the CRAC unit 106 may be avoided in this scenario. As an alternative approach, in this scenario the thermal rate decision module 504 instead could decide to increase the thermal output rate to increase the transfer of thermal energy from the PCM store 114 into the circulated water, which in turn would maintain latent heat capacity in the PCM store 114 in anticipation of the workload spike. Further, a combination of thermal input rate control and output rate control could likewise maintain the latent heat capacity for the workload spike.

As yet another example, the thermal rate decision module 504 may predict that the electricity prices are going to rise in the near future, and thus may decrease the thermal input rate so that the PCM store 114 retains more latent heat capacity, and thus can absorb more thermal energy when electricity prices are higher, thereby allowing the CRAC unit 106 to operate in the near future at a lower performance level, and thus consuming less electricity during high electricity price periods. Conversely, the thermal rate decision module 504 may predict the electricity prices are going to drop in the near future, and thus the thermal rate decision module 504 may increase the thermal input rate so that the CRAC unit 106 can operate at the current time at a lower performance level while the electricity prices are currently high. The thermal rate decision module 504 may change the thermal output rate in a manner inversely proportional to the thermal input rate for analogous reasons.

The thermal rate decision module 504 can use any of a variety of mechanisms to select one or both of the thermal input rate and the thermal output rate for the next control cycle. For example, in one embodiment, the thermal rate decision module 504 can incorporate logic that represents a function to determine a thermal input/output rate based on a set of operational parameters acting as inputs to the function. For example, the function may represent a weighted sum of a normalized representation of a difference between the current workload and a predicted future workload for the next control cycle, a normalized representation of a difference between the current electricity price and a prediction of a future electricity prices, and a normalized representation of a current rate of consumption of the latent heat capacity of the PCM store 114. As another example, a multidimensional curve representing optimal thermal input/output rates for a given set of operational parameters may be determined through simulation or other analysis, and this multidimensional curve then may be utilized by the thermal rate decision module 504 as, for example, a parameterized equation or a look-up table (LUT) that provides a thermal input/output rate for a given input set of operational parameters. In such instances, the LUT, the parameters of the functions, and other configuration information for the thermal input/output rate selection process may be stored as decision configuration information in the data 526 in the data store for access by the thermal rate decision module 504.

FIG. 6 illustrates an example method 600 of operation of the cooling system controller 112 of FIG. 5 to select thermal input rates and thermal output rates that balance multiple objectives in accordance with at least one embodiment. The method 600 represents the decisioning process made for each control cycle of the cooling system controller 112, which may be triggered on a periodic basis (e.g., every X seconds), in response to a trigger or alert (e.g., the computing resources 104 reaching a threshold temperature or the CRAC unit 106 reaching a certain cooling performance metric), or the like. With a control cycle triggered, at block 602 the operational parameter module 502 queries various components of the data center 100 to obtain a set of current operating parameters. The set of operating parameters can include, for example, a current electricity price, a current performance state of the computing resources 104, a current temperature of the computing resources 104, a remaining latent heat capacity of the PCM store 114, a current workload for the computing resources 104, a pending workload for the computing resources, and the like. From these current operating parameters, the operational parameter module 502 can estimate or predict additional operational parameters, such as a predicted future workload of the computing resources from the pending workload parameter, a predicted rate of consumption from the remaining latent heat capacity and a previously-recorded remaining latent heat capacity, a predicted electricity price based on the current electricity price, and the like. The current operational parameters and estimated/predicted operational parameters derived therefrom are collectively referred to herein as “the set of operational parameters.” This set of operational parameters can be added to the operational parameter history database 524 for use as historical information in subsequent control cycles.

At block 604, the thermal rate decision module 504 performs a multivariate analysis using the set of operational parameters to select a thermal input rate for the PCM store 114 for the upcoming control cycle and at block 606 the thermal rate decision module 504 performs a multivariate analysis using the set of operational parameters to select a thermal output rate for the PCM store 114 for the upcoming control cycle. Although FIG. 6 illustrates the process of block 604 preceding the process of block 606, it should be noted that the rate selection processes may be determined in any order. Moreover, in some embodiments, the thermal input rate is selected based in part on the thermal output rate, or vice versa. That is, the selection of at least one of the thermal input rate and the thermal output rate is dependent on the selection of the other, and thus the thermal input rate and thermal output rate may be selected concurrently.

In at least one embodiment, the thermal input and output rates are selected to achieve a desired balance between various objectives, such as the objective of minimizing cooling costs, the objective of implementing minimum CRAC capacity, the objective of maintaining a constant temperature for the computing resources 104, the objective of maintaining additional cooling capacity in reserve for workload spikes, and the like. As noted above, this balancing of objectives may be embodied in one or more rate determination functions, lookup tables, or other decision data structures utilized by the thermal rate decision module 504. To illustrate by way of example, the thermal rate decision module 504 may implement a LUT representative of a multi-dimension curve that represents a desired balance between the remaining currently unused cooling capacity of the CRAC unit 106 and current electricity prices. From this LUT, the thermal rate decision module 504 can use a current electricity price parameter and a current cooling performance parameter to select an appropriate thermal input rate in view of what it would otherwise cost to increase the performance of the CRAC unit 106 to evacuate the thermal energy that otherwise could be absorbed by the PCM store 114. Further, the thermal rate decision module 504 may implement a LUT representative of a multi-dimension cure that represents a desired balance between maintaining a latent heat capacity in reserve and the future electricity prices given the selected thermal input rate, and from this LUT the thermal rate decision module 504 can select a thermal output rate that maintains a desired latent heat capacity at a given electricity price given the thermal input transfer rate.

At block 608 the thermal rate decision module 504 controls the flow rates of the heat transfer system 128 and the cooling loop 127 to implement the selected thermal input rate and the selected thermal output rate, respectively, for the upcoming control cycle. This can include, for example, changing the rate of flow of water or other cooling fluid to match the indicated transfer rate, activating additional cooling loops, changing a blend of water supplies of different temperatures, and the like. The process of blocks 602-608 then may be repeated for the next control cycle.

In some embodiments, certain aspects of the techniques described above may implemented by one or more processors of a processing system executing software. The software comprises one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. In a data center utilizing a phase change material (PCM) store for thermal energy storage, a method comprising:
determining a current set of operational parameters for the data center; and
controlling a net thermal energy transfer to the PCM store based on the current set of parameters.

2. The method of claim 1, wherein the current set of operational parameters includes at least one of: a current electricity price; a future electricity price; a current performance state for a corresponding set of computing resources of the data center; a future performance state for a corresponding set of computing resources of the data center; and a current remaining latent heat capacity of the PCM store.

3. The method of claim 1, wherein:
the current set of operational parameters comprises a current electricity price and a future electricity price; and
controlling the net thermal energy transfer to the PCM store comprises:
increasing a rate of thermal energy transfer to the PCM store responsive to determining the future electricity price is less than the current electricity price; and
decreasing a rate of thermal energy transfer to the PCM store responsive to determining the future electricity price is greater than the current electricity price.

4. The method of claim 1, wherein:
the current set of operational parameters comprises a current performance state for a set of computing resources of the data center and a future performance state for the set of computing resources; and
controlling the net thermal energy transfer to the PCM store comprises:
increasing a rate of thermal energy transfer to the PCM store responsive to determining the future performance state is less than the current performance state; and
decreasing a rate of thermal energy transfer to the PCM store responsive to determining the future performance state is greater than the current performance state.

5. The method of claim 4, wherein:
the current set of operational parameters further includes a current remaining latent heat capacity of the PCM store; and
controlling the net thermal energy transfer to the PCM store comprises implementing a rate of thermal energy transfer to the PCM store further based on the latent heat capacity of the PCM store.

6. The method of claim 1, further comprising:
controlling a net thermal energy transfer from the PCM store to a cooling system of the data center based on the current set of operational parameters.

7. The method of claim 6, wherein:
the current set of operational parameters comprises a current electricity price and a future electricity price; and
controlling a net thermal energy transfer from the PCM store comprises:
increasing a rate of thermal energy transfer from the PCM store to the cooling system responsive to determining the future electricity price is greater than the current electricity price; and
decreasing a rate of thermal energy transfer from the PCM store to the cooling system responsive to determining the future electricity price is less than the current electricity price.

8. A cooling system controller for a set of computing resources of a data center, the cooling system controller comprising:
a first interface to couple to a first flow controller that controls a rate of thermal energy transfer from the set of computing resources to a PCM store from the set of computing resources;
a controller coupled to the first interface and comprising:
an operational parameter module to determine a current set of operational parameters for the data center; and
a thermal rate decision module to manipulate the first flow controller via the first interface to control the rate of thermal energy transfer from the set of computing resources to the PCM store based on the current set of parameters.

9. The cooling system controller of claim 8, wherein the current set of operational parameters includes at least one of: a current electricity price; a future electricity price; a current performance state for a corresponding set of computing resources of the data center; a future performance state for a corresponding set of computing resources of the data center; and a current remaining latent heat capacity of the PCM store.

10. The cooling system controller of claim 8, wherein:
the operational parameter module is to determine a current electricity price and a future electricity price for the set of computing resources; and
the thermal rate decision module is to:
manipulate the first flow controller to increase the rate of thermal energy transfer to the PCM store responsive to determining the future electricity price is less than the current electricity price; and
manipulate the first flow controller to decrease the rate of thermal energy transfer to the PCM store responsive to determining the future electricity price is greater than the current electricity price.

11. The cooling system controller of claim 8, wherein:
the operational parameter module is to determine a current performance state for a set of computing resources of the data center and a future performance state for the set of computing resources; and
the thermal rate decision module is to:
manipulate the first flow controller to increase the rate of thermal energy transfer to the PCM store responsive to determining the future performance state is less than the current performance state; and
manipulate the first flow controller to decrease the rate of thermal energy transfer to the PCM store responsive to determining the future performance state is greater than the current performance state.

12. The cooling system controller of claim 11, wherein:
the operational parameter module further is to determine a current remaining latent heat capacity of the PCM store; and
the thermal rate decision module is to control the rate of thermal energy transfer to the PCM store further based on the latent heat capacity of the PCM store.

13. The cooling system controller of claim 8, further comprising:
a second interface coupled to the controller, the second interface to couple to a second flow controller that controls a rate of thermal energy transfer from the PCM store to a cooling system of the data center; and
wherein the thermal rate decision module further is to manipulate the second flow controller via the second interface to control the rate of thermal energy transfer from the PCM store to the cooling system based on the current set of operational parameters.

14. The cooling system controller of claim 13, wherein:
the operational parameter module is to determine a current electricity price and a future electricity price; and
the thermal rate decision module is to:
manipulate the second flow controller to increase the rate of thermal energy transfer from the PCM store to the cooling system responsive to determining the future electricity price is greater than the current electricity price; and
manipulate the second flow controller to decrease the rate of thermal energy transfer from the PCM store to the cooling system responsive to determining the future electricity price is less than the current electricity price.

15. The cooling system controller of claim 8, wherein:
the set of computing resources comprises computing resources of a server rack;
the PCM store is located at the server rack; and
the first flow controller controls a rate of flow in a heat pipe system that runs between the computing resources of the server rack and the PCM store.

16. The cooling system controller of claim 15, wherein the PCM store is located in at least one of: a casing of the server rack; at least one side of a server unit of the server rack; and a server unit space of the server rack.

17. The cooling system controller of claim 8, wherein:
the set of computing resources comprises computing resources of a server unit of a server rack;
the PCM store is located at the server unit; and
the first flow controller controls a rate of flow in a heat pipe system that runs between the computing resources of the server unit and the PCM store.

18. The cooling system controller of claim 17, wherein the PCM store is located on a circuit board of the server unit.

19. In a data center utilizing a phase change material (PCM) store for thermal energy storage, a method comprising:
controlling a net thermal energy transfer from a set of computing resources to the PCM store based on a least one of a current workload or a future workload of the set of computing resources and based on at least one of a current electricity price and a future energy price.

20. The method of claim 19, further comprising:
controlling a net thermal energy transfer from the PCM store to a cooling system based on a least one of the current electricity price and the future energy price and based on a current remaining latent heat capacity of the PCM store.
